(19) United States
(12) Patent Application Publication
(10) Pub. No.: US 2016/0056097 A1
(43) Pub. Date: Feb. 25, 2016

(54) SEMICONDUCTOR DEVICE WITH INSPECTABLE SOLDER JOINTS

(71) Applicants: Zhigang Bai, Tianjin (CN); Xingshou Pang, Tianjin (CN); Nan Xu, Tianjin (CN); Jinzhong Yao, Tianjin (CN)

(72) Inventors: Zhigang Bai, Tianjin (CN); Xingshou Pang, Tianjin (CN); Nan Xu, Tianjin (CN); Jinzhong Yao, Tianjin (CN)

(21) Appl. No.: 14/556,225

(22) Filed: Nov. 30, 2014

(30) Foreign Application Priority Data
Aug. 20, 2014 (CN) 20141052115.3

(51) Int. Cl. H01L 23/495; H01L 21/52; H01L 21/78; H01L 21/56; H01L 21/311; H01L 21/3205; H01L 23/31; H01L 21/48

(52) U.S. Cl. CPC H01L 23/49555; H01L 23/3157; H01L 23/4952; H01L 23/49582; H01L 21/52; H01L 21/4825; H01L 21/563; H01L 21/311; H01L 21/3205; H01L 21/4842; H01L 21/78

(57) ABSTRACT

A Quad Flat Non-leaded (QFN) semiconductor die package has a semiconductor die mounted on a die flag of a lead frame. A covers the semiconductor die. The housing has a base and sides. There are electrically conductive mounting feet, each of which has an exposed base portion in the base of the housing and an exposed side portion in the one of the sides of the housing. Bond wires electrically connect electrodes of the semiconductor die to respective ones of the mounting feet.

### BACKGROUND OF THE INVENTION

The present invention relates generally to semiconductor packaging and, more particularly, to a lead frame and a semiconductor device with inspectable solder joints using the lead frame.

Semiconductor integrated circuits (ICs) are continually decreasing in size and there is a corresponding demand for such smaller yet denser circuits. At the same time, there is a desire for such circuits to provide the same or more inputs and outputs. Some types of semiconductor IC packages have a housing from which leads (a.k.a. lead fingers) protrude; the leads allow the package to be connected to external circuitry. Such packages may have a large footprint and the lead fingers increase package height.

As an alternative to packages with protruding lead fingers, surface mount semiconductor devices have been developed. An example of a surface mount device is the Quad Flat Non-leaded (QFN) package, which has exposed contact pads or terminals underneath and on four sides of a rectangular package. The QFN is formed with a lead frame and a semiconductor die mounted on a pad or flag of the lead frame. The lead fingers surround the die pad and the die is electrically connected to the lead fingers with bond wires. The lead frame is formed from a sheet of metal and includes the die pad, lead fingers surrounding the die pad, and arms that attach the die pad to a frame. After the electrodes of the die are electrically connected to the lead fingers, the semiconductor die and lead fingers are encapsulated in a plastic material, e.g., moulding compound, leaving only underside sections of the lead fingers exposed. Typically, the partially completed package is then cut (singulated) from the sheet (of lead frames) to form a rectangular package where the underside sections of the lead fingers provide contact pads adjacent the four sides of the package. These contact pads are plated typically with tin to allow for ease of solder joint connection to mounting pads of a circuit board.

Once the package is mounted on a circuit board with the contact pads soldered to corresponding mounting pads on the circuit board, inspection of the resulting solder joints is beneficial in order to detect potential joint defects. However, existing semiconductor packages contact pads make it difficult to realize effective inspection of the solder connection.

### BRIEF DESCRIPTION OF THE DRAWINGS

The invention, together with objects and advantages thereof, may best be understood by reference to the following description of preferred embodiments together with the accompanying drawings in which:

FIG. 1 is a top plan view of part of a lead frame sheet according to an embodiment of the present invention;

FIG. 2 is a cross-sectional side view through 2-2′ of the lead frame sheet of FIG. 1;

FIG. 3 is a die populated wire bonded sheet assembly formed from the lead frame sheet of FIG. 1 according to an embodiment of the present invention;

FIG. 4 is cross-sectional side view through 4-4′ of the die populated wire bonded sheet assembly of FIG. 3.

FIG. 5 is a cross-sectional side view of an encapsulated die assembly formed from the populated wire bonded sheet assembly of FIG. 3 according to an embodiment of the present invention;

FIG. 6 is a cross-sectional side view of an encapsulated die assembly with exposed mounting feet side portions formed from the encapsulated die assembly of FIG. 5 according to an embodiment of the present invention;

FIG. 7 is a cross-sectional side view of an encapsulated die assembly with plated mounting feet formed from the encapsulated die assembly of FIG. 6 according to an embodiment of the present invention;

FIG. 8 is a cross-sectional side view of a QFN package formed from the encapsulated die assembly of FIG. 7 according to an embodiment of the present invention;

FIG. 9 is a cross-sectional side view of a solder mounted assembly formed from the semiconductor die package of FIG. 8 when mounted to a circuit board according to an embodiment of the present invention;

FIG. 10 is a cross-sectional side view of an encapsulated die assembly formed from the populated wire bonded sheet assembly of FIG. 3 according to an embodiment of the present invention;

FIG. 11 is a cross-sectional side view of an encapsulated die assembly with exposed mounting feet side portions formed from the encapsulated die assembly of FIG. 10 according to an embodiment of the present invention;

FIG. 12 is a cross-sectional side view of an encapsulated die assembly with plated mounting feet formed from the encapsulated die assembly of FIG. 11 according to an embodiment of the present invention;

FIG. 13 is a cross-sectional side view of a QFN package formed from the encapsulated die assembly of FIG. 12 according to a second embodiment of the present invention;

FIG. 14 is a cross-sectional side view of a solder mounted assembly formed from the semiconductor die package of FIG. 13 when mounted to a circuit board according to a second embodiment of the present invention; and

FIG. 15 is a flow chart of a method for assembling a semiconductor die package according to an embodiment of the present invention.

### DETAILED DESCRIPTION OF PREFERRED EMBODIMENTS

The detailed description set forth below in connection with the appended drawings is intended as a description of presently preferred embodiments of the invention, and is not intended to represent the only forms in which the present invention may be practised. It is to be understood that the same or equivalent functions may be accomplished by different embodiments that are intended to be encompassed within the spirit and scope of the invention. In the drawings, like numerals are used to indicate like elements throughout. Furthermore, terms “comprises,” “comprising,” or any other variation thereof, are intended to cover a non-exclusive inclusion, such that module, circuit, device components, structures and method steps that comprises a list of elements or steps does not include only those elements but may include other elements or steps not expressly listed or inherent to such module, circuit, device components or steps. An element or step proceeded by “comprises . . . a” does not, without more constraints, preclude the existence of additional identical elements or steps that comprises the element or step.

In one embodiment, the present invention provides a QFN package comprising a semiconductor die mounted on a die flag. A housing covers the semiconductor die. The housing has a base and sides. There are electrically conductive mounting feet, each of which includes an exposed base portion in the base of the housing and an exposed side portion in one of the sides of the housing. Bond wires selectively electrically connect electrodes of the semiconductor die to respective ones of the mounting feet.

In another embodiment, the present invention provides a lead frame sheet with an array of lead frames formed therein. Each of the lead frames includes a surrounding frame that surrounds a die flag. Tie bars extend inwardly from the surrounding frame and support the die flag. There are mounting feet depending from the surrounding frame, each of which includes a base portion and a side portion. The side portion has an end region proximal to the surrounding frame, and is normal to and depends from the surrounding frame, and the base portion is parallel to the surrounding frame.

In another embodiment, the present invention provides a method for assembling a QFN package from a lead frame sheet with an array of lead frames formed therein. Each of the lead frames includes a surrounding frame that surrounds a die flag. Tie bars extending inwardly from the surrounding frame support the die flag. There are mounting feet depending from the surrounding frame, each of the mounting feet includes a base portion and a side portion. The side portion has an end region proximal to the surrounding frame, and is normal to and depends from the surrounding frame, while the base portion is parallel to the surrounding frame. The method comprises populating the sheet with semiconductor dies mounted on the die flags and then selectively electrically connecting electrodes of the semiconductor dies to respective ones of the mounting feet. An encapsulation process is then performed to cover the dies and the sheet with an encapsulating material that leaves the base portions exposed. A singulation process is then performed, removing portions of the housing adjacent the side portions to expose the side portions. A plating process plates the side and base portions with an electrically conductive material.

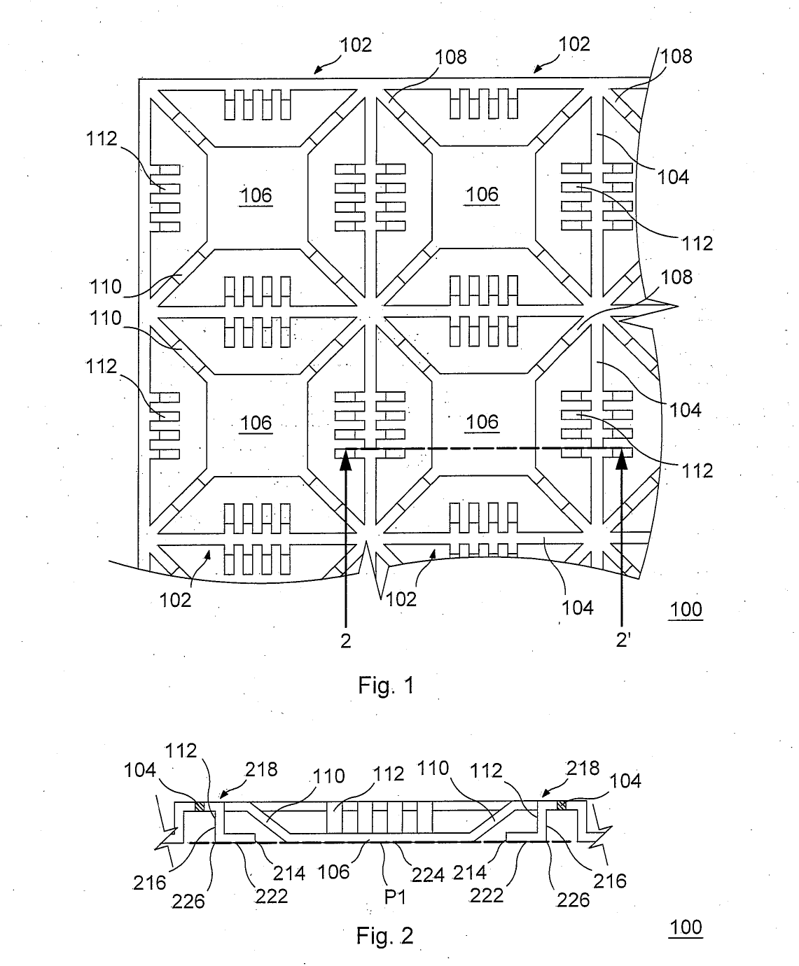

Referring now to FIG. 1, a top plan view of part of a lead frame sheet 100 in accordance with an embodiment of the present invention is shown. The lead frame sheet 100 is an electrically conductive sheet that is typically copper based and has an array of lead frames 102 formed in the sheet 100. The lead frames 102 are normally formed in the sheet 100 by a cutting or punching process and each of the lead frames 102 includes a surrounding frame 104 that surrounds a respective die flag 106 (lead frame flag). Tie bars 108 extend inwardly from the surrounding frame 104 and support the die flag 106. In this embodiment the tie bars 108 have an angled region 110 to provide a down-setting of the die flag 106 relative to the surrounding frame 104. Also, each of the lead frames 102 has mounting feet 112 depending from a respective surrounding frame 104.

FIG. 2 shows a cross-sectional side view, through 2-2′ of the lead frame sheet 100 in accordance with a preferred embodiment of the present invention. As shown, each of the mounting feet 112 includes an integral base portion 214 and a side portion 216. The side portion 216 has an end region 218 proximal to the surrounding frame 104 and the side portion 216 is normal to, and depends from, the surrounding frame 104.

The base portion 214 is distal from and parallel to the surrounding frame 104. Also, the base portion 214 has an underside surface 222 that is parallel, and more specifically planar, with an underside surface 224 of the die flag 106 as illustrated by plane P1. Furthermore, each of the mounting feet 112 has a right angle bend forming a corner edge 226 between the base portion 114 and side portion 116.

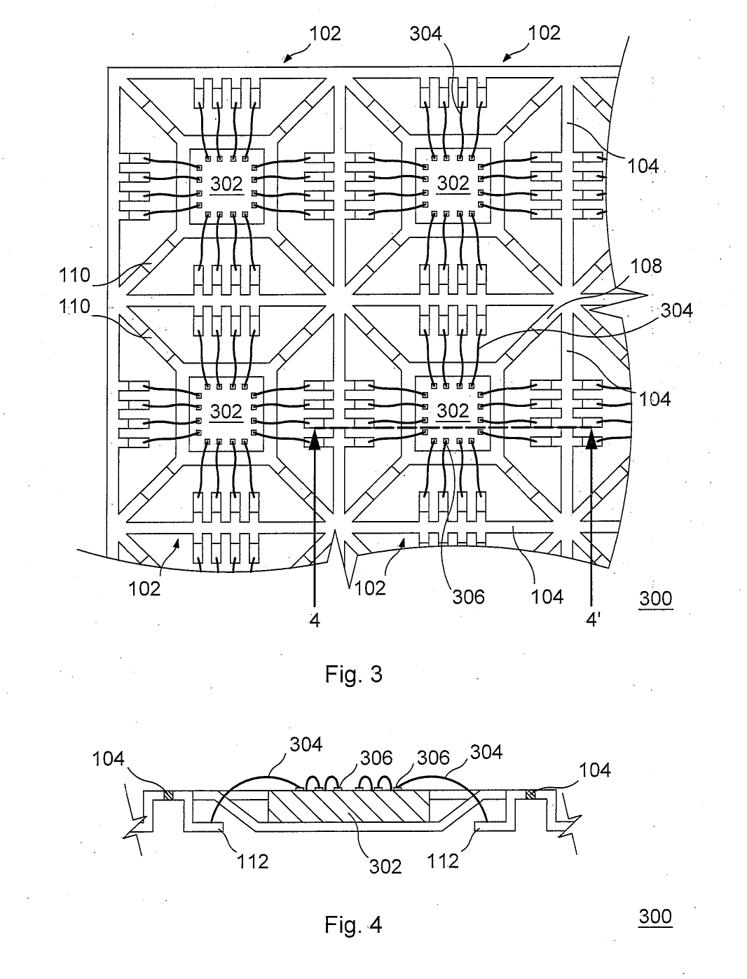

FIG. 3 is a top plan view of a populated wire bonded sheet assembly 300, formed from the lead frame sheet 100, in accordance with an embodiment of the present invention. The populated wire bonded sheet assembly 300 has a semiconductor die 302 mounted on the die flag 106 of a respective one of the lead frames 102. Bond wires 304 selectively electrically connect electrodes 306 of each semiconductor die 302 to a respective ones of the mounting feet 112.

FIG. 4 is a cross-sectional side view, through 4-4′ of the populated wire bonded sheet assembly 300, in accordance with an embodiment of the present invention. In this embodiment the down-setting of the die flag 106 relative to the surrounding frame 104 allows for a relatively thin or low profile since the semiconductor die 302 barely protrudes above an upper plane of the surrounding frame 104.

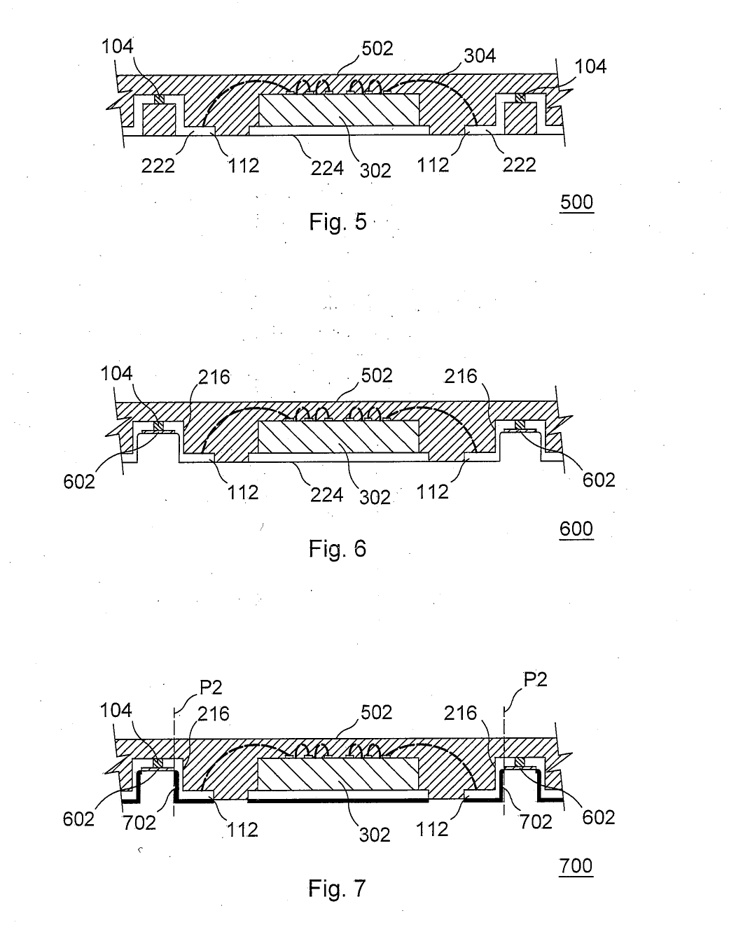

FIG. 5 shows an encapsulated die assembly 500 formed from the populated wire bonded sheet assembly 300, in accordance with a preferred embodiment of the present invention. The encapsulated die assembly 500 includes a housing 502 typically press formed from an encapsulant, of preferably plastics material, that covers the semiconductor die 302. The housing 502 encapsulates the populated wire bonded sheet assembly 300 while leaving the underside surfaces 122 and 124 exposed.

FIG. 6 is a cross-sectional side view of an encapsulated die assembly 600 with exposed mounting feet side portions formed from the encapsulated die assembly 500 according to an embodiment of the present invention. A portion of the housing 502 adjacent the side portions 216 is removed, typically by milling or sawing process, to expose the side portions 216. As shown, a layer 602 of encapsulant that forms the housing 502 remains adjacent the surrounding frame 104. However, this layer 602 may be removed, if required, by adjusting the cut depth of the milling or sawing process.

FIG. 7 is a cross-sectional side view of an encapsulated die assembly with plated mounting feet 700 formed from the encapsulated die assembly 600, according to an embodiment of the present invention. As shown, a plating 702, preferably of tin, has been applied to the exposed mounting feet 112 providing for an extended plating surface. The layer 602 controls the extent of the plating 702 along the side portions 216 of the mounting feet 112. Also shown are singulation lines or cutting planes P2 that are described below.

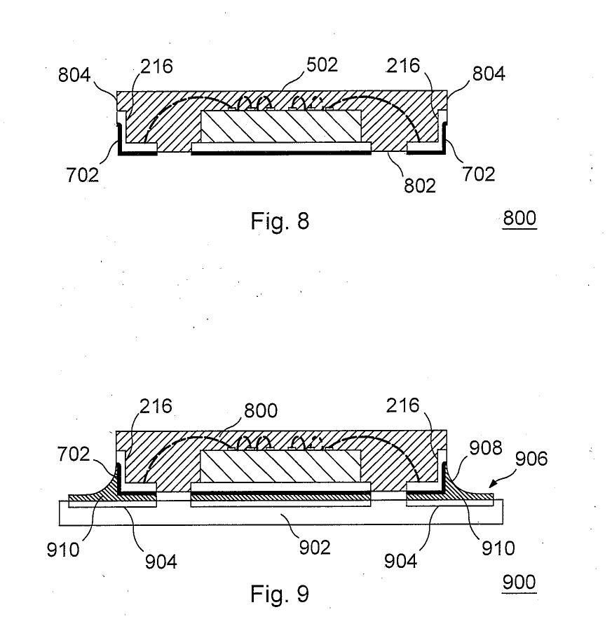

FIG. 8 is a cross-sectional side view of a QFN package 800 formed from the encapsulated die assembly with plated mounting feet 700 according to an embodiment of the present invention. The semiconductor die package 800 has been cut (singulated) from the encapsulated die assembly of 700, typically using a saw, by cutting through the housing 502 and the surrounding frame 104 along the cutting planes P2.

The housing 502 of the semiconductor die package 800 covers the semiconductor die 302 and the housing 502 has a base 802 and sides 804. Each of the electrically conductive mounting feet 112 have a base portion 214 exposed in the base 802 and a side portion 216 exposed in one of the sides 804. The bond wires 304 selectively electrically connect the electrodes 306 of the semiconductor 302 die to a respective one of the mounting feet 112. The exposed side portion 216 is parallel to a respective one of the sides 804 and the exposed base portion 214 is parallel to the base 802 of the housing 502. It will be appreciated by those of skill in the art that the plating step may be performed either before or after the singulation step.

FIG. 9 is a cross-sectional side view of a solder mounted assembly 900 formed from the semiconductor die package 800 when mounted to a circuit board 902 according to an embodiment of the present invention. As shown, the semiconductor die package 800 has been mounted to pads 904 of the circuit board 902 by solder joints 906. The plating 702 on the side portions 216 provides for an enlarged solder fillet 910 which, in turn, provides for improved inspection of the solder joint 906.

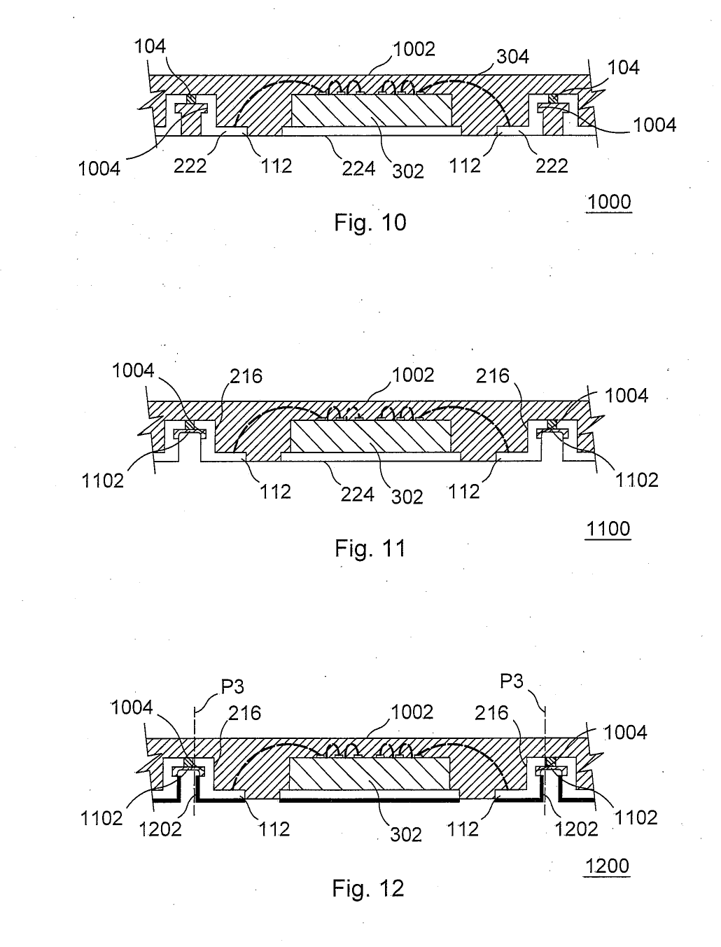

Referring to FIG. 10, an encapsulated die assembly 1000 formed from the populated wire bonded sheet assembly 300, in accordance with another embodiment of the present invention, is shown. The encapsulated die assembly 1000 includes a housing 1002 typically press formed from an encapsulant, of preferably plastics material, covers the semiconductor die 302. The housing 1002 encapsulates the populated wire bonded sheet assembly 300 leaving the underside surfaces 122 and 124 exposed. Also, an outer surface of each side portion 216 has a recess 1004 adjacent the surrounding frame 104, which is normally formed by a cutting or etching process.

FIG. 11 is a cross-sectional side view of an encapsulated die assembly 1100 with exposed mounting feet side portions formed from the encapsulated die assembly 1000. A portion of the housing adjacent the side portions 216 is removed, typically by milling or sawing process, to expose the side portions 216. As shown, a layer 1102 of encapsulant that forms the housing 502 remains adjacent the surrounding frame 104 and in the recesses 1004.

FIG. 12 is a cross-sectional side view of an encapsulated die assembly with plated mounting feet 1200 formed from the encapsulated die assembly 1100. As shown, a plating 1202, preferably of tin, has been applied to the exposed mounting feet 112 providing for an extended plating surface. The layer 1102 controls the extent of the plating 1202 along the side portions 216 of the mounting feet 112. Also shown are singulation lines or cutting planes P3 that are described below.

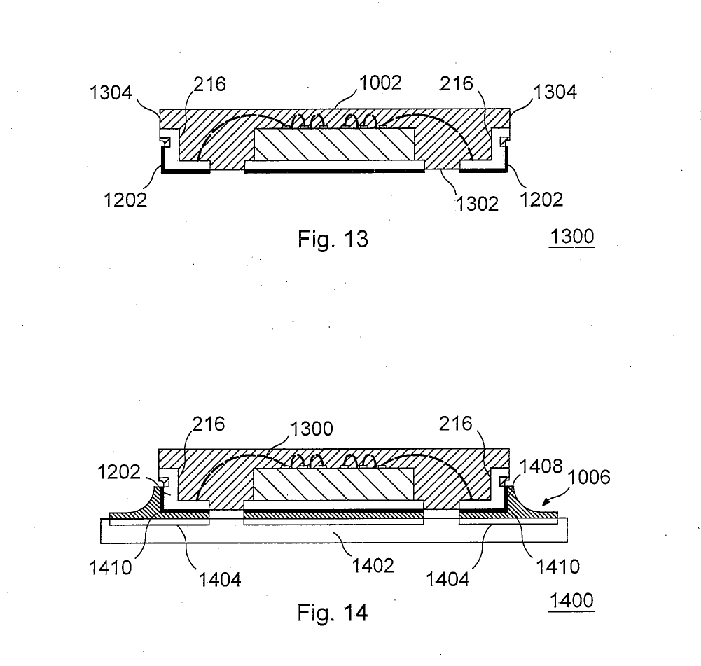

FIG. 13 is a cross-sectional side view of a QFN semiconductor die package 1300 formed from the encapsulated die assembly with plated mounting feet 1200. The semiconductor die package 1300 has been singulated cut (singulated) from the encapsulated die assembly with plated mounting feet 1200 typically using a saw, by cutting through the housing 1002 and the surrounding frame 104 along the cutting planes P3.

The housing 1002 of the semiconductor die package 1300 covers the semiconductor die 302 and the housing 1002 has a base 1302 and sides 1304. Each of the electrically conductive mounting feet 112 has a base portion 214 exposed in the base 1302 and a side portion 216 exposed in one of the sides 1304. The bond wires 304 selectively electrically connect the electrodes 306 of the semiconductor 302 die to respective ones of the mounting feet 112. The exposed side portion 216 is parallel to a respective one of the sides 1304 and the exposed base portion 214 is parallel to the base 1302 of the housing 1302.

FIG. 14 is a cross-sectional side view of a solder mounted assembly 1400 formed from the semiconductor die package 1300 when mounted to a circuit board 1402. As shown, the semiconductor die package 1300 has been mounted to pads 1404 of the circuit board 1402 by solder joints 1406. The plating 1202 on the side portions 216 provides for an enlarged solder fillet 1410 which, in turn, provides for improved inspection of the solder joint 1406.

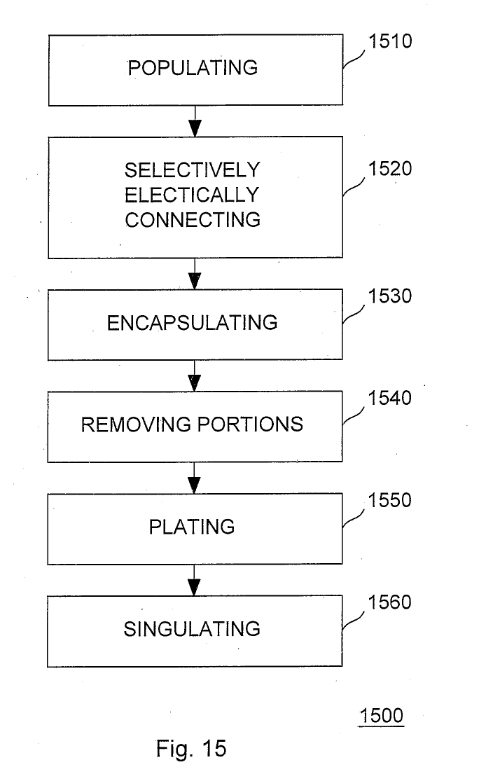

Referring to FIG. 15, a flow chart of a method 1500 for assembling a semiconductor die package according to an embodiment of the present invention is shown. By way of example only, and where appropriate, the method 1500 will be described with reference to the above FIGS. 1-14. In this regard, the method 1500 provides for assembling a QFN semiconductor die package 800, 1300 from a lead frame sheet 100. At a populating block 1510 the sheet 100 is populated with the semiconductor dies 302 that are mounted on the die flags 106. At block 1520, there is performed a wire bonding process to selectively electrically connect the electrodes 306 of the semiconductor dies 302 to respective ones of the mounting feet 112.

At block 1530, an encapsulating step is performed in which the semiconductor dies 302 and the sheet 100 are covered with an encapsulating material to form the housing 502, 1002 that leaves the base portions 214 exposed. After completion of the encapsulating step 1530, the encapsulated die assembly 500, 1000 results.

At block 1540, a cutting process is performed for removing portions of the housing 502, 1002 adjacent the side portions 216 to thereby expose the side portions 216 resulting in the encapsulated die assembly with exposed mounting feet side portions 600, 1100.

At block 1550, the side portions 216 and base portions 214 are plated with an electrically conductive material such as tin to provide the encapsulated die assembly with plated mounting feet 700, 1200.

At block 1560, a singulation process is performed in which the sheet is cut or punched to provide the QFN semiconductor die package 800 or 1300.

The description of the preferred embodiments of the present invention has been presented for purposes of illustration and description, but is not intended to be exhaustive or to limit the invention to the forms disclosed. It will be appreciated by those skilled in the art that changes could be made to the embodiments described above without departing from the broad inventive concept thereof. It is understood, therefore, that this invention is not limited to the particular embodiment disclosed, but covers modifications within the spirit and scope of the present invention as defined by the appended claims.

1. A Quad Flat Non-leaded (QFN) package, comprising:
a semiconductor die mounted on a die flag;
a housing that covers the semiconductor die, wherein the housing has a base and sides;
electrically conductive mounting feet, wherein each of the mounting feet has a base portion exposed in the base of the housing and a side portion exposed in one of the sides of the housing; and
bond wires electrically connecting electrodes of the semiconductor die to respective ones of the mounting feet,
wherein each side portion has a recess adjacent the surrounding frame.

2. The QFN package of claim 1, wherein each of the mounting feet has a right angle bend forming a corner edge between the exposed base portion and exposed side portion.

3. The QFN package of claim 2, wherein the exposed side portion is parallel to a respective one of the sides.

4. The QFN package of claim 2, wherein the exposed base portion is parallel to the base of the housing.

5. The QFN package of claim 1, wherein the housing is formed from a molding compound.

6. The QFN package of claim 1, wherein the exposed base portion and exposed side portion are coated with electrically conductive plating.

7. The QFN package of claim 6, wherein the electrically conductive plating is tin based plating.

8. The QFN package of claim 1, wherein the mounting feet are located adjacent each of the sides of the housing.

9. (canceled)

10. A lead frame sheet with an array of lead frames formed therein, wherein each of the lead frames comprises:
a die flag for receiving a semiconductor die;
a frame that surrounds the die flag;
tie bars extending inwardly from the frame and supporting the die flag; and
mounting feet depending from the frame, wherein each of the mounting feet has a base portion and a side portion, the side portion having an end region proximal to the surrounding frame and normal to and depending from the surrounding frame, and the base portion is parallel to the surrounding frame,
wherein a right angle bend is formed in a corner edge between the base portion and side portion, and each side portion has a recess adjacent the surrounding frame.

11. The lead frame sheet of claim 10, wherein the base portion is parallel with a surface of the die flag.

12. The lead frame sheet of claim 11, wherein the base portion is planar with a surface of the die flag.

13. (canceled)

14. (canceled)

15. A method for assembling a Quad Flat Non-leaded (QFN) semiconductor die package from a lead frame sheet with an array of lead frames formed therein, each of the lead frames comprising a surrounding frame that surrounds a die flag, tie bars extending inwardly from the surrounding frame and supporting the die flag, mounting feet depending from the surrounding frame, each of the mounting feet including a base portion and a side portion, the side portion having an end region proximal to the surrounding frame and wherein the side portion is normal to and depends from the surrounding frame and the base portion is parallel to the surrounding frame, the method comprising:
populating the sheet with semiconductor dies by mounting the dies on the die flags;
electrically connecting electrodes of the semiconductor dies to respective ones of the mounting feet;
encapsulating the semiconductor dies and the sheet with an encapsulating material that leaves the base portions exposed;
removing portions of the housing adjacent the side portions to thereby expose the side portions;
plating the side portions and base portions with an electrically conductive material; and
singulating the sheet to provide the QFN semiconductor die package.

16. The method of claim 15, wherein the base portion is parallel with a surface of the die mount.

17. The method of claim 16, wherein the base portion is planar with a surface of the die mount

18. The method of claim 15, wherein the plating step is performed after the singulation step.

19. The method of claim 15, wherein each side portion has a recess adjacent the surrounding frame.

20. The method of claim 15, wherein the encapsulating material is a mold compound.
